(19) United States
(12) Patent Application Publication
(10) Pub. No.: US 2023/0272256 A1
(43) Pub. Date: Aug. 31, 2023

(54) THERMALLY CONDUCTIVE ALIGNED MATERIALS AND METHODS OF MAKING AND USE THEREOF

(71) Applicant: Boston Materials, Inc., Billerica, MA (US)

(72) Inventors: Chunzhou Pan, Quincy, MA (US); Caitlin Nicole Hirschler, Newton, MA (US); Darcy Hornberger, Woburn, MA (US); Anvesh Gurijala, Lancaster, MA (US)

(73) Assignee: Boston Materials, Inc., Billerica, MA (US)

(21) Appl. No.: 18/104,844

(22) Filed: Feb. 2, 2023

Related U.S. Application Data
(60) Provisional application No. 63/314,808, filed on Feb. 28, 2022.

(51) Int. Cl. C09K 5/06; H05K 7/20; H01M 10/653

(52) U.S. Cl. CPC C09K 5/063; H05K 7/2039; H01M 10/653

(57) ABSTRACT

The present disclosure generally relates to thermally conductive aligned materials for a variety of purposes, including as thermal interface materials for semiconductor devices or other applications. Certain aspects are directed to compositions comprising discontinuous fibers that may be substantially aligned, e.g., defining a substrate. The composition may also include a polymer or a phase change material in contact with at least some of the discontinuous fibers. The discontinuous fibers may include carbon fibers in some cases. In some cases, the discontinuous fibers are aligned so as to facilitate heat transfer, e.g., along the direction that the fibers are aligned. Other aspects are generally directed to devices using such compositions, methods of making such compositions, kits including such compositions, or the like.

### RELATED APPLICATIONS

This application claims the benefit of U.S. Provisional Patent Application Ser. No. 63/314,808, filed Feb. 28, 2022, entitled “Thermally Conductive Aligned Materials and Methods of Making and Use Thereof,” incorporated herein by reference in its entirety.

### FIELD

The present disclosure generally relates to thermally conductive aligned materials for a variety of purposes, including as thermal interface materials for semiconductor devices or other applications.

### BACKGROUND

A thermal interface material is a material having a relatively low thermal impedance that is used to conduct heat between a first location (e.g., a heat source) and a second location (e.g., a heat sink). The thermal interface material thus can be used to help thermally communicate the first location to the second location.

Thermal interface materials are often used to dissipate heat in electronic equipment. For example, semiconductor devices in computers often produce significant amount of heat, which could damage the chips or other components. Accordingly, thermal interface materials may be used to help connect semiconductor devices to suitable heat sinks, for example cooling fins.

However, many thermal interface materials are inefficient and do not have suitably high thermal conductivities. Accordingly, improvements are needed.

### SUMMARY

The present disclosure generally relates to thermally conductive aligned materials for a variety of purposes, including as thermal interface materials for semiconductor devices or other applications. The subject matter of the present disclosure involves, in some cases, interrelated products, alternative solutions to a particular problem, and/or a plurality of different uses of one or more systems and/or articles.

In one aspect, the present disclosure is directed to a composition. In one set of embodiments, the composition comprises a plurality of discontinuous fibers defining a substrate, and a phase change material in contact with at least some of the discontinuous fibers. In some cases, at least 30 vol % of the fibers within the substrate are substantially aligned. In certain embodiments, the phase change material exhibits a phase change between 0° C. and 80° C.

The composition, in another set of embodiments, comprises a plurality of discontinuous fibers defining a substrate, and a polymer in contact with at least some of the discontinuous fibers. In some embodiments, at least 30 vol % of the fibers within the substrate are substantially aligned. In certain embodiments, the polymer having a viscosity of less than 500 cP at a temperature of 60° C.

In yet another set of embodiments, the composition comprises a substrate comprising no more than 30 vol % of a metal, where the substrate has a density of less than 2.7 g/cm³ and a heat conductivity of at least 5 W/m K, and a phase change material in contact with at least some of the discontinuous fibers, where the phase change material exhibits a phase change between 0° C. and 300° C.

In still another set of embodiments, the composition comprises a substrate having a density of less than 2.7 g/cm³ and exhibiting an anisotropic heat conductivity of at least 5 W/m K in a through-thickness direction.

In another aspect, the present disclosure is directed to a device. In one set of embodiments, the device comprises a heat source, a cooling apparatus, and a composition in physical contact with the heat source and the cooling apparatus. In some embodiments, the composition comprises (a) a plurality of discontinuous fibers defining a substrate, at least 30 vol % of the fibers within the substrate being substantially aligned, and (b) a phase change material in contact with at least some of the discontinuous fibers, the phase change material exhibiting a phase change between 0° C. and 80° C.

The device, in another set of embodiments, comprises a heat source, a cooling apparatus, and a composition in physical contact with the heat source and the cooling apparatus. In some embodiments, the composition comprises (a) a plurality of discontinuous fibers defining a substrate, at least 30 vol % of the fibers within the substrate being substantially aligned, and (b) a polymer in contact with at least some of the discontinuous fibers, the polymer having a viscosity of less than 500 cP at a temperature of 60° C.

In yet another set of embodiments, the device comprises a heat source, a cooling apparatus, and a composition in physical contact with the heat source and the cooling apparatus. In certain embodiments, the composition comprises a plurality of discontinuous fibers defining a substrate, and the composition has a through-thickness heat conductivity of at least 30 W/m K. In some cases, at least 30 vol % of the fibers within the substrate are substantially aligned.

The device, in still another set of embodiments, comprises a heat source, a cooling apparatus, and a composition in physical contact with the heat source and the cooling apparatus. In certain embodiments, the composition exhibits anisotropic heat conductivity, and has a heat conductivity of at least 30 W/m K in a through-thickness direction.

In another set of embodiments, the device comprises a heat source, a cooling apparatus, and a composition in physical contact with the heat source and the cooling apparatus. In some embodiments, the composition comprises (a) a substrate comprising no more than 30 vol % of a metal, where the substrate has a density of less than 2.7 g/cm³ and a heat conductivity of at least 5 W/m K, and/or (b) a phase change material in contact with at least some of the discontinuous fibers, where the phase change material exhibits a phase change between 0° C. and 300° C.

The device, in yet another set of embodiments, comprises a heat source, a cooling apparatus, and a composition in physical contact with the heat source and the cooling apparatus. In some embodiments, the composition comprises (a) a substrate comprising no more than 30 vol % particles, where the substrate has a density of less than 2.7 g/cm³ and a heat conductivity of at least 5 W/m K, and/or (b) a phase change material in contact with at least some of the discontinuous fibers, where the phase change material exhibits a phase change between 0° C. and 300° C.

Yet another aspect is generally directed to a method. In one set of embodiments, the method comprises providing a plurality of discontinuous fibers defining a substrate, and exposing at least some of the discontinuous fibers to a phase change material. In some embodiments, at least 30 vol % of the fibers within the substrate are substantially aligned. In certain embodiments, the phase change material exhibits a phase change between 0° C. and 80° C. and forms a discrete layer on top of at least one side of the substrate.

The method, in another set of embodiments, comprises providing a plurality of discontinuous fibers defining a substrate, and exposing at least some of the discontinuous fibers to a polymer. In some embodiments, the polymer has a viscosity of less than 500 cP at a temperature of 60° C. In certain cases, at least 30 vol % of the fibers within the substrate are substantially aligned.

In yet another set of embodiments, the composition comprises a plurality of discontinuous fibers defining a substrate, and a matrix positioned in physical contact with a first side of the substrate but not with a second side of the substrate. In some embodiments, at least 30 vol % of the fibers within the substrate are substantially aligned. In some cases, the matrix immobilizes first ends of the discontinuous fibers but not second ends.

In another aspect, the present disclosure encompasses methods of making one or more of the embodiments described herein, for example, thermally conductive aligned materials. In still another aspect, the present disclosure encompasses methods of using one or more of the embodiments described herein, for example, thermally conductive aligned materials.

Other advantages and novel features of the present disclosure will become apparent from the following detailed description of various non-limiting embodiments of the disclosure when considered in conjunction with the accompanying figures.

### BRIEF DESCRIPTION OF THE DRAWINGS

Non-limiting embodiments of the present disclosure will be described by way of example with reference to the accompanying figures, which are schematic and are not intended to be drawn to scale. In the figures, each identical or nearly identical component illustrated is typically represented by a single numeral. For purposes of clarity, not every component is labeled in every figure, nor is every component of each embodiment of the disclosure shown where illustration is not necessary to allow those of ordinary skill in the art to understand the disclosure. In the figures:

FIG. 1 is an SEM image of a composition in accordance with one embodiment, illustrating substantially aligned discontinuous fibers;

FIG. 2 is an SEM image of a composition in accordance with another embodiment, showing embedded carbon fibers;

FIG. 3 is an SEM image of a composition in accordance with yet another embodiment, showing carbon fibers embedded in paraffin wax;

FIG. 4 illustrates thermal impedance of a composition in still another embodiment; and

FIGS. 5A-5B illustrate non-limiting examples of certain devices in accordance with various embodiments.

### DETAILED DESCRIPTION

The present disclosure generally relates to thermally conductive aligned materials for a variety of purposes, including as thermal interface materials for semiconductor devices or other applications. Certain aspects are directed to compositions comprising discontinuous fibers that may be substantially aligned, e.g., defining a substrate. The composition may also include a polymer or a phase change material in contact with at least some of the discontinuous fibers. The discontinuous fibers may include carbon fibers in some cases. In some cases, the discontinuous fibers are aligned so as to facilitate heat transfer, e.g., along the direction that the fibers are aligned. Other aspects are generally directed to devices using such compositions, methods of making such compositions, kits including such compositions, or the like.

One aspect of the present disclosure is generally directed to thermal interface materials (TIM) and compositions. These may be used, for example, to conduct heat between a first location (e.g., a heat source) and a second location (e.g., a heat sink). Such compositions may be positioned between a semiconductor device (e.g., a heat source or a heat generating body) and a heat sink or a cooling apparatus (e.g., a heat radiating body). In some embodiments, thermally conductive carbon fibers can be used to transport heat quickly and efficiently through the material. In addition, in some embodiments, such compositions may be used to provide electromagnetic interference (EMI) shielding, e.g., instead or in addition to thermal transport.

In one set of embodiments, materials such as polymers or phase change materials may be used within the composition. Non-limiting examples include silicones, acrylics, waxes, and other materials, including those discussed in more detail herein. In one set of embodiments, such compositions may be used to ensure good thermal contact between a first location and a second location, e.g., between a heat source and a heat sink or a cooling apparatus. In addition, in certain embodiments, the compositions may include filler, such as ceramic or metallic fillers, e.g., in addition to or instead of a polymer or a phase change material.

In one set of embodiments, compositions such as those described herein may contain a plurality of discontinuous fibers, which may be substantially aligned in some cases. It should be noted that such alignment need not be perfect, but at least some of the fibers within the composition may generally exhibit an alignment that is within 20° or less of the average alignment of the plurality of the fibers, e.g., as discussed herein. In addition, in some embodiments, such fibers may be aligned at a relatively high volume or packing fraction. For example, the fibers may be present within the composition such that at least 30 vol % of the composition comprise such fibers. Higher volume percentages are also possible in other embodiments, e.g., as discussed herein. Such fibers, e.g., when substantially aligned, may be particularly effective at transporting heat from a first location and a second location, e.g., due to the alignment and directionality of the fibers. In contrast, many other compositions used for thermal interface materials have much lower fiber concentrations or densities, and typically any fibers that may be present cannot transport significant amounts of heat, e.g., due to their low concentrations.

Accordingly, certain embodiments such as those discussed herein may be directed to substrates containing or defined by such discontinuous fibers, which may be substantially aligned in some cases. In some cases, a polymer or a phase change material may be added. For example, such materials may be infused into the substrate using techniques such as applied pressure, gravity, capillary action, or the like, as discussed in more detail herein. In some cases, additional materials may be coated onto the substrate.

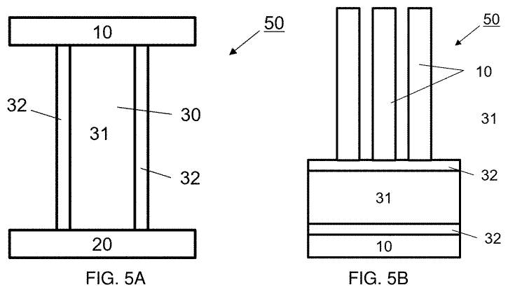

Certain non-limiting examples of such systems are now discussed with respect to FIG. 5. In FIG. 5A, example device 50 comprises a heat source 20 (e.g., a first location), a cooling apparatus 10 (e.g., a second location), and a composition 30 in physical contact with the heat source and the cooling apparatus. For example, heat source 20 may be a semiconductor microchip, or other heat sources such as those described herein. Similarly, cooling apparatus 10 may be a heat sink, a metal with a relatively high heat conductivity, or other cooling apparatus such as any of those described herein.

Between heat source 20 and cooling apparatus 10 is composition 30. Composition 30, in this non-limiting example, includes substrate 31, and phase change material 32. In some cases, e.g., as described herein, substrate 31 may include a plurality of discontinuous fibers, which may be substantially aligned in some cases. Phase change material 32 may include a material that begins to soften (e.g., become gummy or runny, etc.) or liquefy when exposed to heat from device 50 (e.g., from heating source 20). For instance, phase change material 32 may include a wax, or other materials including any described herein. Although two phase change materials are present in this figure, this is by way of example only, and in other cases, there may be fewer or more phase change materials present in a composition.

Another non-limiting example in illustrated in FIG. 5B. In this figure, cooling apparatus 10 may take the form of one or more cooling fins. Composition 30 is positioned between the cooling fins and heat source 20, and is positioned such that phase change material 32 is in direct physical contact with heat source 20, while substrate 31 is not. Substrate 31 may include a plurality of discontinuous fibers, which aligned in any suitable orientation, e.g., parallel or orthogonal to the substrate itself, parallel or orthogonal to heat source 20, etc.

The above discussion is a non-limiting example of certain embodiment of the present invention that can be used to produce certain thermally conductive aligned materials. However, other embodiments are also possible. Accordingly, more generally, various aspects of the invention are directed to various systems and methods for thermally conductive aligned materials.

For example, various aspects are generally directed to compositions that can conduct heat between a first location (e.g., a heat source) and a second location (e.g., a heat sink). In some instances, the composition may be used as a thermal interface material that can be used to help thermally communicate the first location to the second location. In one set of embodiments, a composition such as discussed herein may have relatively high thermal conductivity. For example, the composition may have an overall heat conductivity of at least 3 W/m K, at least 5 W/m K, at least 10 W/m K, at least 20 W/m K, at least 25 W/m K, at least 30 W/m K, at least 35 W/m K, at least 40 W/m K, at least 45 W/m K, at least 50 W/m K, at least 60 W/m K, at least 75 W/m K, at least 100 W/m K, at least 200 W/m K, at least 250 W/m K, at least 300 W/m K, at least 350 W/m K, at least 400 W/m K, at least 450 W/m K, at least 500 W/m K, at least 600 W/m K, at least 750 W/m K, etc.

In one set of embodiments, the composition may have a density of less than 5 g/ml, less than 4.5 g/ml, less than 4 g/ml, less than 3.5 g/ml, less than 3 g/ml, less than 2.9 g/ml, less than 2.8 g/ml, less than 2.7 g/ml, less than 2.6 g/ml, less than 2.5 g/ml, less than 2.4 g/ml, less than 2.2 g/ml, less than 2 g/ml, less than 1.5 g/ml, etc. Without wishing to be bound by any theory, it is believed that relatively low densities for use in heat sinks and certain other applications, e.g., as discussed herein, have not been previously achievable since such materials often rely on metals that have relatively high densities. Surprisingly, as is discussed herein, relatively high overall heat conductivities may be achieved in accordance with certain embodiments without relying on metals or other high-density materials.

Thus, for example, in some embodiments, the composition may include a plurality of discontinuous fibers, and a polymer or a phase change material in contact with at least some of the discontinuous fibers. The discontinuous fibers may include carbon fibers, and/or other fibers formed using materials such as those described herein. In some cases, the plurality of discontinuous fibers may be substantially aligned which, surprisingly, allows for significantly improved heat transport, e.g., along the direction of alignment or a through-thickness direction. In some cases, the through-thickness direction may be in a direction substantially orthogonal to the plane of the substrate. Such compositions may result in improved heat transport, in certain embodiments, due to close packing of the discontinuous fibers. For instance, at least 30 vol % (or other percentages such as described herein) of the fibers may be substantially aligned, which may result in improved heat transport within the composition.

In addition, in certain embodiments, the composition may be useful as a shield against electromagnetic interference, instead or in addition to heat transport. In some cases, by increasing the bulk electrical conductivity of the material, the material may be able to absorb electromagnetic waves, thereby shielding against electromagnetic interference. The electromagnetic shielding may be partial or total, depending on the application. In some cases, the shielding can reduce the coupling of radio waves, electromagnetic fields, electrostatic fields, or the like, e.g., due to the conductive elements within the composition, e.g., carbon or other fibers such as those described herein. In addition, in some embodiments, increased thermal conductivity of the composition may also correspond to increased electrical conductivity, and/or increased shielding against electromagnetic interference.

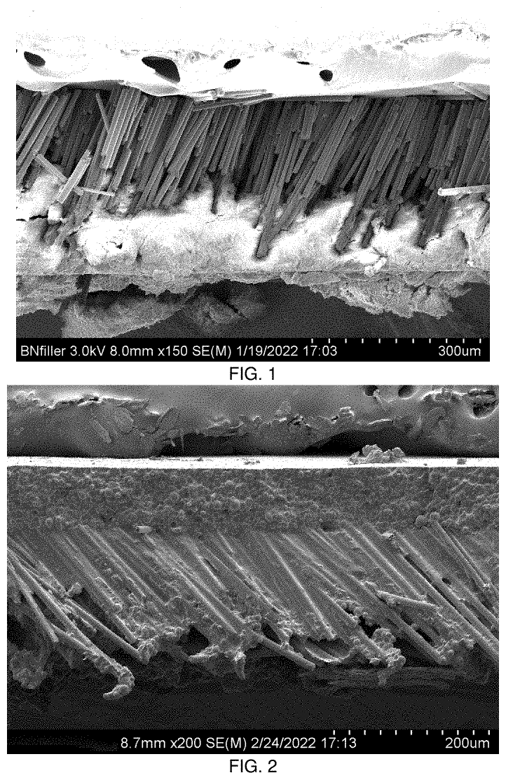

Thus, one aspect is generally directed to a plurality of discontinuous fibers. In some embodiments, there may be a relatively high number of discontinuous fibers that are present, e.g., such that they can define a substrate. A non-limiting example is shown in FIG. 1. The discontinuous fibers may form a relatively large percentage of the substrate. For example, at least 20 vol %, at least 30 vol %, at least 40 vol %, at least 50 vol %, at least 60 vol %, at least 70 vol %, at least 80 vol %, at least 90 vol %, at least 95 vol %, at least 97 vol %, or at least 99 vol % of the substrate may be formed from discontinuous fibers.

In addition, in certain embodiments, some or all of the discontinuous fibers may be substantially aligned. Methods for aligning discontinuous fibers are discussed in more detail below. However, it should be understood that the alignment need not be perfect. For example, in some cases as described herein, at least 5% or more of the fibers within a substrate or composite may exhibit an alignment that is within 20° or less of the average alignment of the plurality of the fibers.

In addition to discontinuous fibers, there may also be materials such as polymers or phase change materials present within the composition, according to certain aspects. Without wishing to be bound by any theory, it is believed that such materials may be particularly useful for being able to form good thermal contact between the materials and other components of the device, such as heat sources, heat sinks, cooling apparatuses, etc. In some cases, such materials, when exposed to relatively warm temperatures, may partially or fully soften or liquefy, which may improve thermal contact, e.g., with such components. For instance, in one set of embodiments, the composition may include a phase change material that begins to soften (e.g., become gummy or runny, etc.) or liquefy when the device it is in is used (e.g., producing heat). As a non-limiting example, the device may include a semiconductor microchip, e.g., within a computer, and the microchip may be heated during use up to temperatures of between 40° C. and 80° C., between 50° C. and 70° C., etc. Even higher temperatures may be possible in some embodiments. In such cases, the phase change material may soften or liquefy at such high temperatures, which may improve thermal contact with the semiconductor microchip, e.g., facilitating the transport of heat away from it.

Any of a wide variety of phase change materials may be used. In general, a phase change material may change phase due to heat, e.g., from a heat source. For example, the material may change phase from a solid to a liquid (e.g., by heating through Tₘ), from a crystalline state to an amorphous or rubbery state (e.g., by heating through T_{g}), or the like. Without wishing to be bound by any theory, it is believed that a phase change material may be useful in certain cases because it may be able to flow when heated, e.g., to seal cracks, poor connections, etc., and/or because it absorbs heat energy (e.g., to effect the change of phase) rather than increasing in temperature, at least until the phase change is completed. In certain embodiments, one or more than one phase change material may be present.

In some cases, the phase change material is one that exhibits a phase change at an operating temperature of the device. For example, the phase change material may exhibit a phase change at a temperature of at least 0° C., at least 10° C., at least 20° C., at least 30° C., at least 40° C., at least 50° C., at least 60° C., at least 70° C., at least 80° C., at least 90° C., at least 100° C., at least 125° C., at least 150° C., at least 175° C., at least 200° C., at least 250° C., at least 275° C., at least 300° C., etc. In some cases, the phase change material may exhibit a phase change at a temperature of no more than 300° C., no more than 275° C., no more than 250° C., no more than 225° C., no more than 200° C., no more than 175° C., no more than 150° C., no more than 125° C., no more than 100° C., no more than 90° C., no more than 80° C., no more than 70° C., no more than 60° C., no more than 50° C., no more than 40° C., no more than 30° C., no more than 20° C., no more than 10° C., etc. Combinations of any of these are also possible. For example, the phase change material may exhibit a phase change between 0° C. and 80° C., between 40° C. and 80° C., between 50° C. and 70° C., between 30° C. and 50° C., between 40° C. and 60° C., between 0° C. and 300° C., or the like.

In addition, in certain embodiments, the phase change material may be one that flows relatively easy, e.g., at temperatures above the phase change temperature. For example, the phase change material may have a viscosity of less than 1000 cP, less than 500 cP, less than 100 cP, less than 50 cP, or less than 10 cP at a temperature of 40° C., 50° C., or 60° C. The plurality of discontinuous fibers may be partially or fully in contact with the phase change material. For instance, in one embodiment, the plurality of discontinuous fibers may be completely embedded within the phase change material. In another embodiment, the plurality of discontinuous fibers may contact the phase change material at their first ends but not a second ends. For instance, the second ends may be in contact with a different material, or may be free in some embodiments.

A variety of materials may be used as a phase change material. Non-limiting examples of phase change materials include silicones, acrylics, thermoplastics, or the like. Additional examples include trimethylolethane, lithium nitrate, manganese nitrate, manganese chloride, etc.

As another example, in one set of embodiments, the phase change material may comprise a wax. The wax may include alkanes and/or lipids, and may be naturally occurring or artificially produced. In some cases, the waxes are substantially water insoluble. In some cases, the wax may have a melting temperature of at least 40° C., or other phase change temperatures such as any of those described herein. Non-limiting examples of waxes include paraffin wax, polyethylene wax, hydrocarbon wax, beeswax, cetyl palmitate, plant waxes, montan wax, lauric acid, or the like.

As yet another example, the phase change material may comprise a salt hydrate. Non-limiting examples of salt hydrates include potassium fluoride tetrahydrate, manganese nitrate hexahydrate, calcium chloride hexahydrate, calcium bromide hexahydrate, lithium nitrate hexahydrate, sodium sulfate decahydrate, sodium carbonate decahydrate, sodium orthophosphate dodecahydrate, zinc nitrate hexahydrate, sodium sulfate decahydrate, etc. For example, in one embodiment, the salt hydrate may have a formula NaCl·Na₂SO₄·10H₂O.

As still another example, the phase change material may comprise a eutectic. Typically, a eutectic is a mixture of two or more substances that has a lower melting point than any of the substances forming the eutectic. For example, the eutectic may have a melting temperature of between 0° C. and 80° C., or other phase change temperatures such as any of those described herein. As non-limiting examples, the eutectic may be an organic-organic eutectic or an organic-inorganic eutectic. Specific non-limiting examples include myristic acid and stearic acid, Mg(NO₃)₂·6H₂O and glutaric acid, ethylene glycol distearate, or the like.

Still other examples of eutectics include, but are not limited to, tetradecane and hexadecane, tetradecane and docosane, tetradecane and geneicosane, caprylic acid and lauric acid, tetradecane and tetradeconol, pentadecane and heneicosane, caprylic acid and palmitic acid, dodecanol and caprylic acid, pentadecane and docosane, pentadecane and octadecane, hexadecane and tetradecane, capric acid and lauric acid and cineole, capric acid and lauric acid and methyl salicylate, capric acid and lauric acid and pentadecane, capric acid and lauric acid, triethylolethane and water and urea, capric acid and lauric acid and eugenol, capric acid and lauric acid, butyl palmitate and butyl sterate, methyl palmitate and methyl sterate, capric acid and palmitic acid, octadecane and docosane, octadecane and heneicosane, capric acid and steric acid, etc.

In addition, it should be understood that a phase change material is not necessarily required. In another set of embodiments, the composition may include a polymer, which may be relatively soft polymer in some cases, e.g., in addition to or instead of a phase change material. For example, in one set of embodiments, the polymer may be one that is able to readily flow at an operating temperature of the device. For example, the polymer may exhibit flow properties at a temperature of at least 0° C., at least 10° C., at least 20° C., at least 30° C., at least 40° C., at least 50° C., at least 60° C., at least 70° C., etc., and/or no more than 80° C., no more than 70° C., no more than 60° C., no more than 50° C., no more than 40° C., no more than 30° C., no more than 20° C., no more than 10° C., etc. Combinations of any of these are also possible. For example, the polymer may be one that is able to readily flow at temperatures of between 0° C. and 80° C., between 40° C. and 80° C., between 50° C. and 70° C., between 30° C. and 50° C., between 40° C. and 60° C., or the like. For example, the polymer may have a viscosity of less than 1000 cP, less than 500 cP, less than 100 cP, less than 50 cP, less than 10 cP, or less than 5 cP at these temperatures. As discussed above, in some cases, such polymers may be useful because of their ability to flow when heated, e.g., to seal cracks, poor connections, etc.

Examples of such polymers include, but are not limited to, silicones, acrylics, phase change materials, thermosets, and/or thermoplastics, etc. Specific non-limiting examples include epoxy, polyaryletherketone (PAEK), polyimide (PI), polyamide-imide (PAI), polyetheretherketone (PEEK), polyetherketone (PEK), polyphenylesulfone (PPSU), polyethersulfone (PES), polyetherimide (PEI), polysulfone (PSU), polyphenylene sulfide (PPS), polyvinylidene fluoride (PVDF), polytetrafluoroethylene (PTFE), perfluoroalkoxy alkanes (PFA), polyamide 46 (PA46), polyamide 66 (PA66), polyamide 12 (PA12), polyamide 11 (PA11), polyamide 6 (PA6), polyamide 6.6 (PA6.6), polyamide 6.6/6 (PA6.6/6), amorphous polyamide (PA6-3-T), polyethylene terephthalate (PET), polyphthalamide (PPA), liquid crystal polymer (LCP), polycarbonate (PC), polybutylene terephthalate (PBT), polyoxymethylene (POM), polyphenyl ether (PPE), polymethyl methacrylate (PMMA), polypropylene (PP), polyethylene (PE), high density polyethylene (HDPE), acrylonitrile styrene acrylate (ASA), styrene acrylonitrile (SAN), acrylonitrile butadiene styrene (ABS), polybenzimidazole (PBI), polyvinyl chloride (PVC), poly-para-phenylene-copolymer (PPP), polyacrylonitrile, polyethylenimine, polyetherketonetherketoneketone (PEKEKK), ethylene tetrafluoroethylene (ETFE), polychlorotrifluoroethylene (PCTFE), polymethylpentene (PMP), etc.

As mentioned, the composition may include a plurality of discontinuous fibers in various aspects. In some cases, the discontinuous fibers may be substantially aligned, e.g., defining a substrate. In some embodiments, at least 20 vol %, at least 30 vol %, at least 40 vol %, at least 50 vol %, at least 60 vol %, at least 70 vol %, at least 80 vol %, at least 90 vol %, at least 95 vol %, at least 97 vol %, at least 99 vol %, etc. of the substrate may contain discontinuous fibers. In addition, at least 20 vol %, at least 30 vol %, at least 40 vol %, at least 50 vol %, at least 60 vol %, at least 70 vol %, at least 80 vol %, at least 90 vol %, at least 95 vol %, at least 97 vol %, or at least 99 vol % of the substrate may be formed from discontinuous fibers.

The discontinuous fibers may be formed or include any of a wide variety of materials, and one or more than one type of material may be present. For example, the discontinuous fibers may comprise materials such as carbon (e.g., carbon fibers), basalt, silicon carbide, silicon nitride, aramid, zirconia, nylon, boron, alumina, silica, borosilicate, mullite, nitride, boron nitride, graphite, glass, a polymer (including any of those described herein), or the like. The discontinuous fibers may include any natural and/or any synthetic material, and may be magnetic and/or non-magnetic.

In addition, in some cases, the discontinuous fibers may be formed from materials having relatively high thermal conductivity. For instance, in various embodiments, the discontinuous fibers may have thermal conductivities of at least 5 W/m K, at least 10 W/m K, at least 100 W/m K, at least 200 W/m K, at least 250 W/m K, at least 300 W/m K, at least 350 W/m K, at least 400 W/m K, at least 450 W/m K, at least 500 W/m K, at least 600 W/m K, at least 750 W/m K, at least 900 W/m K, at least 1000 W/m K, etc.

The discontinuous fibers, in some embodiments, may be at least substantially aligned. Methods for aligning discontinuous fibers are discussed in more detail herein. Various alignments are possible, and in some cases, can be determined optically or microscopically, e.g. Thus, in some cases, the alignment may be determined qualitatively. However, it should be understood that the alignment need not be perfect. In some cases, at least 5%, at least 10%, at least 25%, at least 50%, at least 75%, at least 85%, at least 90%, or at least 95% of the fibers may be substantially aligned, or may exhibit an alignment that is within 20°, within 15°, within 10°, or within 5° of the average alignment of the plurality of the fibers, e.g., within a sample of the substrate.

In addition, in some cases, the average alignment of the fibers may be oriented to be at at least 45°, least 60°, at least 65°, at least 70°, at least 75°, at least 85°, or at least 87° relative to the plane of the substrate at that location. Without wishing to be bound by any theory, it is believed that alignment of the discontinuous fibers substantially orthogonal to the substrate within the composition may serve to provide structural reinforcement of the substrate and/or the ability to transfer heat preferentially in a direction along the direction of the discontinuous fibers, e.g., such that the composition may exhibit anisotropic heat conductivity. For instance, the composition may exhibit a heat conductivity in one direction of at least 3 W/m K, at least 5 W/m K, at least 10 W/m K, at least 30 W/m K, at least 50 W/m K, at least 100 W/m K, 250 W/m K, at least 500 W/m K, at least 750 W/m K, etc. For instance, this may be in a direction defined by the average alignment of the discontinuous fibers, or a through-thickness direction of a substrate, e.g., substantially perpendicular to the plane of the substrate. In some embodiments, this may allow improved heat transfer, e.g., away from a heat source.

While others have suggested packing fibers in a substrate, it is believed that higher fiber volume fractions were previously unachievable, e.g., in thermal interface materials. Without wishing to be bound by any theory, it is believed that this may be due to higher electrostatic interactions that cause fiber agglomeration, and/or higher viscosities of polymer resins that can prevent consistent dispersion. Accordingly, certain embodiments as discussed herein are generally directed to fiber volume fractions (e.g., of substantially aligned fibers such as those discussed herein) of at least 40% fiber volume, at least 45% fiber volume, at least 50% fiber volume, at least 55% fiber volume, at least 60% fiber volume, at least 65% fiber volume, at least 70% fiber volume, etc.

A variety of techniques may be used to align the discontinuous fibers in various embodiments, including magnetic fields, shear flow, or the like, as are discussed in more detail below. As a non-limiting example, magnetic particles, including those discussed herein, can be attached to the fibers, and a magnetic field may then be used to manipulate the magnetic particles. For instance, the magnetic field may be used to move the magnetic particles into a substrate, and/or to align the discontinuous fibers. The magnetic field may be constant or time-varying (e.g., oscillating), for instance, as is discussed herein. For example, an applied magnetic field may have a frequency of 1 Hz to 500 Hz and an amplitude of 0.01 T to 10 T. Other examples of magnetic fields are described in more detail below.

In some cases, the discontinuous fibers may have an average length, or characteristic dimension, of at least 1 nm, at least 3 nm, at least 5 nm, at least 10 nm, at least 30 nm, at least 50 nm, at least 100 nm, at least 300 nm, at least 500 nm, at least 1 micrometer, at least 3 micrometers, at least 5 micrometers, at least 10 micrometers, at least 20 micrometers, at least 30 micrometers, at least 50 micrometers, at least 100 micrometers, at least 200 micrometers, at least 300 micrometers, at least 500 micrometers, at least 1 mm, at least 2 mm, at least 3 mm, at least 5 mm, at least 10 mm, at least 15 mm, etc. In certain embodiments, the discontinuous fibers may have an average length, or characteristic dimension, of no more than 5 cm, no more than 3 cm, no more than 2 cm, no more than 1.5 cm, no more than 1 cm, no more than 5 mm, no more than 3 mm, no more than 2 mm, no more than 1 mm, no more than 500 micrometers, no more than 300 micrometers, no more than 200 micrometers, no more than 100 micrometers, no more than 50 micrometers, no more than 30 micrometers, no more than 20 micrometers, no more than 10 micrometers, no more than 5 micrometers, no more than 3 micrometers, no more than 1 micrometers, no more than 500 nm, no more than 300 nm, no more than 100 nm, no more than 50 nm, no more than 30 nm, no more than 10 nm, no more than 5 nm, etc. Combinations of any of these are also possible. For example, the plurality of discontinuous fibers may have an average length of between 1 mm and 5 mm.

In addition, the discontinuous fibers may also have any suitable average diameter. For instance, the discontinuous fibers may have an average diameter of at least 5 micrometers, at least 10 micrometers, at least 20 micrometers, at least 30 micrometers, at least 50 micrometers, at least 100 micrometers, at least 200 micrometers, at least 300 micrometers, at least 500 micrometers, at least 1 mm, at least 2 mm, at least 3 mm, at least 5 mm, at least 1 cm, at least 2 cm, at least 3 cm, at least 5 cm, at least 10 cm, etc. In certain embodiments, the discontinuous fibers may have an average diameter of no more than 10 cm, no more than 5 cm, no more than 3 cm, no more than 2 cm, no more than 1 cm, no more than 5 mm, no more than 3 mm, no more than 2 mm, no more than 1 mm, no more than 500 micrometers, no more than 300 micrometers, no more than 200 micrometers, no more than 100 micrometers, no more than 50 micrometers, no more than 30 micrometers, no more than 20 micrometers, no more than 10 micrometers, no more than 5 micrometers, etc. Combinations of any of these are also possible. For example, the discontinuous fibers may have an average diameter of between 5 micrometers and 50 micrometers, 10 micrometers and 100 micrometers, between 50 micrometers and 500 micrometers, between 100 micrometers and 5 mm, etc.

In certain embodiments, the discontinuous fibers may have a length that is at least 10 times or at least 50 times its thickness or diameter, on average. In some cases, the fibers may have an average aspect ratio (ratio of fiber length to diameter or thickness) of at least 3, at least 5, at least 10, at least 30, at least 50, at least 100, at least 300, at least 500, at least 1,000, at least 3,000, at least 5,000, at least 10,000, at least 30,000, at least 50,000, or at least 100,000. In some cases, the average aspect ratio may be less than 100,000, less than 50,000, less than 30,000, less than 10,000, less than 5,000, less than 3,000, less than 1,000, less than 500, less than 300, less than 100, less than 50, less than 30, less than 10, less than 5, etc. Combinations of any of these are also possible in some cases; for instance, the aspect ratio may be between 5, and 100,000.

At least some of the discontinuous fibers may be uncoated. In some cases, however, some or all of the discontinuous fibers may be coated. The coating may be used, for example, to facilitate the adsorption or binding of particles, such as magnetic particles, onto the fibers, or for other reasons. As one non-limiting example, at least some of the discontinuous fibers are coated with sizing. Some examples of coatings or sizings include, but are not limited to, polypropylene, polyurethane, polyamide, phenoxy, polyimide, epoxy, or the like. These can be introduced, for example, as a solution, dispersion, emulsion, etc. As other examples, the fibers may be coated with a surfactant, a silane coupling agent, an epoxy, glycerine, polyurethane, an organometallic coupling agent, or the like. Non-limiting examples of surfactants include oleic acid, sodium dodecyl sulfate, sodium lauryl sulfate, etc. Non-limiting examples of silane coupling agents include amino-, benzylamino-, chloropropyl-, disulfide-, epoxy-, epoxy/melamine-, mercapto-, methacrylate-, tertasulfido-, ureido-, vinyl-, isocynate-, and vinly-benzyl-amino-based silane coupling agents. Non-limiting examples of organometallic coupling agents include aryl- and vinyl-based organometallic coupling agents.

As mentioned, in one set of embodiments, at least some of the discontinuous fibers may be carbon fibers. The carbon fibers may be aligned in a magnetic field directly or indirectly, e.g., using magnetic particles or other techniques such as those discussed herein. For instance, some types of carbon fibers are diamagnetic, and can be directly moved using an applied magnetic field. Thus, certain embodiments are directed to fibers that are substantially free of paramagnetic or ferromagnetic materials could still be aligned using an external magnetic field. For example, if any paramagnetic or ferromagnetic materials are present, they may form less than 5%, less than 1%, less than 0.5%, less than 0.3%, less than 0.1%, less than 0.05%, less than 0.03%, less than 0.01%, less than 0.005%, less than 0.003%, or less than 0.001% (by mass) of the material.

A variety of carbon fibers may be obtained commercially, including diamagnetic carbon fibers. In some cases, carbon fibers can be produced from polymer precursors such as polyacrylonitrile (PAN), rayon, pitch, or the like. In some cases, carbon fibers can be spun into filament yarns, e.g., using chemical or mechanical processes to initially align the polymer atoms in a way to enhance the final physical properties of the completed carbon fibers. Precursor compositions and mechanical processes used during spinning filament yarns may vary. After drawing or spinning, the polymer filament yarns can be heated to drive off non-carbon atoms (carbonization or pyrolization), to produce final carbon fiber. In some embodiments, such techniques may be used to produce carbon fiber with relatively high carbon content, e.g., at least 90%, or other contents as described herein.

Non-limiting examples of carbon fibers include, for instance, pitch- and/or polymer-based (e.g. ex-PAN or ex-Rayon) variants, including those commercially-available. In some cases, these may include intermediate/standard modulus (greater than 200 GPa) carbon fibers, high modulus (greater than 300 GPa), or ultra-high modulus (greater than 500 GPa) carbon fibers.

In one set of embodiments, the carbon fibers have a relatively high carbon content. Without wishing to be bound by any theory, it is believed that such fibers may exhibit diamagnetic properties that allows them to be oriented with low-energy magnetic fields. In general, diamagnetism is the repulsion of a material to an applied magnetic field by generation of an induced magnetic field that is opposite in direction to the applied magnetic field. A material is typically categorized as diamagnetic if it lacks noticeable paramagnetic or ferromagnet contributions to the overall magnetic response. In many cases, the magnetic response of diamagnetic materials is very weak and negligible. However, relatively high magnetic fields can induce a noticeable physical response in such diamagnetic materials.

Thus, in some cases, carbon fibers exhibiting relatively highly-oriented molecular structures may exhibit anisotropic, high-diamagnetism diamagnetic properties. Such diamagnetic properties may allow them to be oriented with relatively weak magnetic fields, such as is described herein. For example, in one set of embodiments, an applied magnetic field may generate a strong induced magnetic field in the C—C bonds of a carbon fiber in the opposite direction of the applied magnetic field. Certain types of carbon fibers may possess a high degree of C—C bonds parallel to the in-fiber direction, which may create an anisotropic diamagnetic response. Thus, such carbon fibers can be subjected to a magnetic torque that is neutralized when the carbon fiber aligns fully-parallel to the applied magnetic field. Accordingly, by applying a suitable magnetic field, the carbon fibers may be aligned due to such diamagnetic properties. This response may be sufficient to overcome gravitational, viscous, and/or interparticle steric effects.

For instance, in certain embodiments, the carbon fibers may have a carbon content of greater than 80%, greater than 90%, greater than 92%, greater than 94%, greater than 95%, greater than 96%, greater than 97%, greater than 98% greater than 99%, or greater than 99.5% by mass. Such carbon fibers may be obtained commercially in some cases. For example, the carbon fibers may be produced pyrolytically e.g., by “burning” or oxidizing other components that can be removed (e.g., by turning into a gas), leaving behind a carbon fiber with a relatively high carbon content. Other methods of making carbon fibers are also possible, e.g., as discussed in detail herein.

The carbon fibers may also exhibit substantial alignment of the C—C bonds within the carbon fibers in some instances. For instance, at least 50%, at least 60%, at least 70%, at least 75%, at least 80%, at least 85%, at least 90%, or at least 95% of the carbon fibers may exhibit substantial alignment of the C—C bonds. Such alignment may be determined, for example, using wide angle x-ray diffraction (WAXD), or other techniques known to those of ordinary skill in the art.

In one set of embodiments, the carbon fibers (or other discontinuous fibers) may have a relatively high modulus (tensile modulus, which is a measure of stiffness). Typically, higher modulus fibers are stiffer and lighter than low modulus fibers. Carbon fibers typically have a higher modulus when force is applied parallel to the fibers, i.e., the carbon fibers are anisotropic. In some embodiments, the carbon fibers (or other discontinuous fibers) may have a modulus (e.g., when force is applied parallel to the fibers) of at least 100 GPa, at least 200 GPa, at least 300 GPa, at least 400 GPa, at least 500 GPa, at least 600 GPa, at least 700 GPa, etc. It is believed that more flexible carbon fibers may exhibit less alignment, i.e., carbon fibers having a low modulus may have subtle physical responses to magnetic fields, or have no response, rather than align within an applied magnetic field.

In one set of embodiments, the carbon fibers (or other discontinuous fibers) may exhibit an anisotropic diamagnetic response when free-floating within a liquid (e.g., water, oil, polymer resin, polymer melt, metal melt, an alcohol such as ethanol, or another volatile organic compound), and a magnetic field is applied. For example, in some cases, the carbon fibers may align when a suitable magnetic field is applied, i.e., indicative of a diamagnetic response. In some cases, the magnetic field may be at least 100 mT, at least 200 mT, at least 300 mT, at least 500 mT, at least 750 mT, at least 1 T, at least 1.5 T, at least 2 T, at least 3 T, at least 4 T, at least 5 T, at least 10 T, etc. In some cases, at least 30%, at least 40%, at least 50%, at least 60%, at least 70%, at least 80%, or at least 90%, of the free-floating carbon fibers within the liquid may exhibit alignment when a suitable magnetic field is applied.

Typically, a fiber has a shape such that one orthogonal dimension (e.g., its length) is substantially greater than its other two orthogonal dimensions (e.g., its width or thickness). The fiber may be substantially cylindrical in some cases. As mentioned, the carbon fibers may be relatively stiff, in some instances; however, a carbon fiber need not be perfectly straight (e.g., its length may still be determined along the fiber itself, even if it is curved).

As mentioned, in one set of embodiments, particles such as magnetic particles may be added, for example, to align the discontinuous fibers, or for other applications. The particles may be adsorbed or otherwise bound to at least some of the discontinuous fibers. In some cases, the particles may coat some or all of the discontinuous fibers and/or the continuous fibers. This may be facilitated by a coating of material as discussed herein, although a coating is not necessarily required to facilitate the adsorption of the particles.

If the particles are magnetic, the particles may comprise any of a wide variety of magnetically susceptible materials. For example, the magnetic materials may comprise one or more ferromagnetic materials, e.g., containing iron, nickel, cobalt, alnico, oxides of iron, nickel, cobalt, rare earth metals, or an alloy including two or more of these and/or other suitable ferromagnetic materials. In some cases, the magnetic particles may have a relative permeability of at least 2, at least 5, at least 10, at least 20, at least 40, at least 100, at least 200, at least 500, at least 1,000, at least 2,000, at least 5,000, or at least 10,000.

However, it should be understood that not all of the particles are necessarily magnetic. In some cases, non-magnetic particles may be used, e.g., in addition to and/or instead of magnetic particles. Non-limiting examples of nonmagnetic particles include glass, polymer, metal, or the like. In addition, in some embodiments, no particles are present.

The particles (if present) may be spherical or non-spherical, and may be of any suitable shape or size. The particles may be relatively monodisperse or come in a range of sizes. In some cases, the particles may have a characteristic dimension, on average, of at least 10 micrometers, at least 20 micrometers, at least 30 micrometers, at least 50 micrometers, at least 100 micrometers, at least 200 micrometers, at least 300 micrometers, at least 500 micrometers, at least 1 mm, at least 2 mm, at least 3 mm, at least 5 mm, at least 1 cm, at least 1.5 cm, at least 2 cm, at least 3 cm, at least 5 cm, at least 10 cm, etc. The particles may also have an average characteristic dimension of no more than 10 cm, no more than 5 cm, no more than 3 cm, no more than 2 cm, no more than 1.5 cm, no more than 1 cm, no more than 5 mm, no more than 3 mm, no more than 2 mm, no more than 1 mm, no more than 500 micrometers, no more than 300 micrometers, no more than 200 micrometers, no more than 100 micrometers, no more than 50 micrometers, no more than 30 micrometers, no more than 20 micrometers, no more than 10 micrometers, etc. Combinations of any of these are also possible. For example, the particles may exhibit a characteristic dimension of or between 100 micrometer and 1 mm, between 10 micrometer and 10 micrometer, etc. The characteristic dimension of a nonspherical particle may be taken as the diameter of a perfect sphere having the same volume as the nonspherical particle.

In addition, in some aspects, the substrate may further comprise fillers or additional materials, e.g., in addition to discontinuous fibers. For example, in one set of embodiments, the substrate comprises a plurality of continuous fibers. The continuous fibers may have a length that, on average, is substantially longer than the cross-sectional dimension of the discontinuous fibers. For example, the continuous fibers may have an average length of at least about 0.5 cm, at least 1 cm, at least 2 cm, at least 3 cm, at least 5 cm, at least 10 cm, etc. In certain embodiments, the continuous fibers may have an average diameter of no more than 10 cm, no more than 5 cm, no more than 3 cm, no more than 2 cm, no more than 1 cm, no more than 0.5 cm, or the like. Combinations of any of these are also possible; for example, the continuous fibers may have an average length of between 1 cm and 10 cm, between 10 cm and 100 cm, etc. Longer average lengths are also possible in some instances.

The continuous fibers may be woven together (e.g. bidirectional, multidirectional, quasi-isotropic, etc.), and/or non-woven (e.g., unidirectional, veil, mat, etc.). In certain embodiments, at least some of the continuous fibers are substantially parallel, and/or orthogonally oriented relative to each other, although other configurations of continuous fibers are also possible. In certain embodiments, the continuous fibers may together define a fabric or other substrate, e.g., a textile, a tow, a filament, a yarn, a strand, or the like. In some cases, the substrate may have one orthogonal dimension that is substantially less than the other orthogonal dimensions (i.e., the substrate may have a thickness). The continuous fibers may also comprise any of a wide variety of materials, and one type or more than one type of fiber may be present within the substrate. Non-limiting examples include carbon, basalt, silicon carbide, aramid, zirconia, nylon, boron, alumina, silica, borosilicate, mullite, cotton, or any other natural or synthetic fibers.

In some instances, the continuous fibers may comprise a relatively large portion of the composite. For example, in certain embodiments, the continuous fibers may comprise at least 1%, at least 2%, at least 3%, at least 4%, at least 5%, at least 7%, at least 10%, at least 15%, at least 20%, at least 25%, at least 30%, at least 35%, at least 40%, at least 45%, at least 50%, at least 55%, at least 60%, at least 65%, at least 70%, at least 75%, at least 80%, at least 85%, at least 90%, at least 95%, or at least 97% of the mass or volume of the composite. In some cases, the continuous fibers comprise no more than 97%, no more than 95%, no more than 90%, no more than 85%, no more than 80%, no more than 70%, no more than 60%, no more than 50%, no more than 40%, no more than 30%, no more than 20%, or no more than 10% of the mass or volume of the composite. Combinations of any of these are also possible.

In some cases, one or more fillers may be present in the substrate. For instance, in certain embodiments, the substrate may further comprise one or more ceramics, such as boron nitride, alumina, titania, or the like. In addition, in some embodiments, the substrate may further comprise one or more metals, such as aluminum, copper, silver, tin, gold, etc. In addition, in one embodiment, such materials present within the substrate may be formed by fusing particles together, e.g., during formation of the substrate. Other materials may also be present in the substrate in some cases as well.

As discussed, certain aspects are generally directed to compositions, for example, comprising a plurality of discontinuous fibers and a phase change material, or other materials such as those described herein. In some cases, the composition is generally planar, and/or may contain one (or more) substrates. However, it should be understood that the substrate or the composition need not be a mathematically-perfect planar structure (although it can be); for instance, a substrate, or a composition may also be deformable, curved, bent, folded, rolled, creased, or the like. As examples, the substrate, may have an average thickness of at least about 0.1 micrometers, at least about 0.2 micrometers, at least about 0.3 micrometers, at least about 0.5 micrometers, at least about 1 micrometer, at least about 2 micrometers, at least about 3 micrometers, at least about 5 micrometers, at least about 10 micrometers, at least about 30 micrometers, at least about 50 micrometers, at least about 100 micrometers, at least about 300 micrometers, at least about 500 micrometers, at least about 1 mm, at least about 2 mm, at least about 3 mm, at least about 5 mm, at least about 1 cm, at least about 3 cm, at least about 5 cm, at least about 10 cm, at least about 30 cm, at least about 50 cm, at least about 100 cm, etc. In certain instances, the average thickness may be less than 100 cm, less than 50 cm, less than 30 cm, less than 10 cm, less than 5 cm, less than 3 cm, less than 1 cm, less than 5 mm, less than 2 mm, less than 3 mm, less than 1 mm, less than 500 micrometers, less than 300 micrometers, less than 100 micrometers, less than 50 micrometers, less than 30 micrometers, less than 10 micrometers, less than 5 micrometers, less than 3 micrometers, less than 1 micrometers, less than 0.5 micrometers, less than 0.3 micrometers, or less than 0.1 micrometers. Combinations of any of these are also possible in certain embodiments. For instance, the average thickness may be between 0.1 and 5,000 microns, between 10 and 2,000 microns, between 50 and 1,000 microns, or the like. The thickness may be uniform or non-uniform across the substrate. Also, the substrate, may be deformable in some cases.

In certain embodiments, the composition may have an areal weight of at least 50 g/m² of the composition, and in some embodiments, at least 100 g/m², at least 150 g/m², at least 200 g/m², at least 250 g/m², at least 300 g/m², at least 400 g/m², at least 500 g/m², at least 750 g/m², at least 1000 g/m² of the composition. It will be understood by those of ordinary skill in the art that the area is the bulk or overall area of the composition, not the individual area of discontinuous fibers that may be present.

The composition, in some cases, may contain additional layers or materials, e.g., in addition to these. For example, the substrate may be one of a number of layers within the composition. Other layers within the composition may include polymers, composite materials, metal, ceramics, or the like. For example, the composition may be consolidated with another layer to form a composite structure.

In certain embodiments, compositions such as these may be used as heat sink materials, and/or to conduct heat between a first location and a second location. A variety of compositions are possible, for example comprising discontinuous fibers such as those described herein, e.g., that may be aligned within a substrate. However, it should be understood that in other embodiments, other compositions and methods may be used, for example, as heat sink materials, and/or to conduct heat between a first location and a second location. In certain cases, relatively high overall heat conductivities may be achieved in accordance with certain embodiments without relying on metals or other high-density materials. As a non-limiting example, in one embodiment, the material may have a density of less than 2.7 g/mL and/or a thermal conductivity of at least 20 W/m K, e.g., in a through-thickness direction.

In other examples, such as discussed herein, the composition may have a heat conductivity of at least 3 W/m K, at least 5 W/m K, at least 10 W/m K, at least 20 W/m K, at least 25 W/m K, at least 30 W/m K, at least 35 W/m K, at least 40 W/m K, at least 45 W/m K, at least 50 W/m K, at least 60 W/m K, at least 75 W/m K, at least 100 W/m K, at least 200 W/m K, at least 250 W/m K, at least 300 W/m K, at least 350 W/m K, at least 400 W/m K, at least 450 W/m K, at least 500 W/m K, at least 600 W/m K, at least 750 W/m K, etc. In certain embodiments, the heat conductivity may be the heat conductivity in a through-thickness direction, e.g., in a direction substantially orthogonal to the plane of the substrate. In addition, in some cases, the composition may have may have a density of less than 5 g/ml, less than 4.5 g/ml, less than 4 g/ml, less than 3.5 g/ml, less than 3 g/ml, less than 2.9 g/ml, less than 2.8 g/ml, less than 2.7 g/ml, less than 2.6 g/ml, less than 2.5 g/ml, less than 2.4 g/ml, less than 2.2 g/ml, less than 2 g/ml, less than 1.5 g/ml, etc.

In certain embodiments, such materials may include a plurality of discontinuous fibers, e.g., as discussed herein. The discontinuous fibers may include carbon fibers, and/or other fibers formed using materials such as those described herein. However, other materials are also possible in certain embodiments. For example, in one embodiment, the material may comprise a composite of particles (e.g., thermally conductive particles) and polymer. In another embodiment, the material may comprise a ceramic, a metal, or the like.

In one set of embodiments, the material may comprise a metal. For example, the metal may be a pure metal, or a metal alloy. Non-limiting examples of metals include aluminum, zinc, copper, magnesium, nickel, silver, gold, or the like. In some cases, alloys or combinations of these and/or other metals may be used. In addition, the metal may be solid, or porous in some embodiments. Other examples of metals include any of those described herein.

In another set of embodiments, the material may comprise a ceramic. Non-limiting examples of ceramics include metal or non-metal oxides, metal or non-metal nitrides, metal or non-metal carbides, metal or non-metal borides, graphite, or the like. Specific non-limiting examples include boron nitride, titanium diboride, aluminum nitride, silicon nitride, silicon carbide, graphite, aluminum oxide, magnesium oxide, zinc oxide, beryllium oxide, antimony oxide, silicon oxide, etc. In some cases, alloys or combinations of these and/or other ceramics may be used. In addition, the ceramic may be solid, or porous in some embodiments. Other examples of ceramics include any of those described herein.

In another set of embodiments, the material may comprise particles. The particles may be thermally conductive in some embodiments. The particles may include metal particles (e.g., comprising metals such as those described above), ceramic particles (e.g., comprising ceramics such as those described above), or the like. Specific non-limiting examples of metals include aluminum, zinc, copper, magnesium, nickel, etc. Examples of ceramics include, but are not limited to, oxides, nitrides, carbides, borides, graphite; specific non-limiting examples include boron nitride, titanium diboride, aluminum nitride, silicon nitride, silicon carbide, graphite, aluminum oxide, magnesium oxide, zinc oxide, beryllium oxide, antimony oxide, silicon oxide, etc.

The particles may be spherical or non-spherical, and may be of any suitable shape or size. For example, the particles may be present as spherical particles, platelets, fibers, or the like. The particles may be relatively monodisperse or come in a range of sizes. In some cases, the particles may have a characteristic dimension, on average, of at least 10 micrometers, at least 20 micrometers, at least 30 micrometers, at least 50 micrometers, at least 100 micrometers, at least 200 micrometers, at least 300 micrometers, at least 500 micrometers, at least 1 mm, at least 2 mm, at least 3 mm, at least 5 mm, at least 1 cm, at least 1.5 cm, at least 2 cm, at least 3 cm, at least 5 cm, at least 10 cm, etc. The particles within the composite may also have an average characteristic dimension of no more than 10 cm, no more than 5 cm, no more than 3 cm, no more than 2 cm, no more than 1.5 cm, no more than 1 cm, no more than 5 mm, no more than 3 mm, no more than 2 mm, no more than 1 mm, no more than 500 micrometers, no more than 300 micrometers, no more than 200 micrometers, no more than 100 micrometers, no more than 50 micrometers, no more than 30 micrometers, no more than 20 micrometers, no more than 10 micrometers, etc. Combinations of any of these are also possible. For example, the particles may exhibit a characteristic dimension of or between 100 micrometer and 1 mm, between 10 micrometer and 10 micrometer, etc. The characteristic dimension of a nonspherical particle may be taken as the diameter of a perfect sphere having the same volume as the nonspherical particle.

In some embodiments, the particles may comprise a relatively large portion of the material. For example, in certain embodiments, the particles may comprise at least 1%, at least 2%, at least 3%, at least 4%, at least 5%, at least 7%, at least 10%, at least 15%, at least 20%, at least 25%, at least 30%, at least 35%, at least 40%, at least 45%, at least 50%, at least 55%, at least 60%, at least 65%, at least 70%, at least 75%, at least 80%, at least 85%, at least 90%, at least 95%, or at least 97% of the volume of the composite. In some cases, the particles comprise no more than 97%, no more than 95%, no more than 90%, no more than 85%, no more than 80%, no more than 70%, no more than 60%, no more than 50%, no more than 45%, no more than 40%, no more than 35% no more than 30%, no more than 25%, no more than 20%, no more than 15%, no more than 10%, no more than 7%, no more than 5%, no more than 4%, no more than 3%, no more than 2%, or no more than 1% of the volume of the material. Combinations of any of these are also possible.

In another set of embodiments, the material may comprise polymers, e.g., thermoset and/or thermoplastic polymers. Non-limiting examples of thermoset polymers include thermosetting alkyd, bismaleimide polymer, bismaleimide triazine polymer, cyanate ester polymer, vinyl ester polymer, benzocyclobutene polymer, diallyl phthalate polymer, epoxy, hydroxymethylfuran polymer, melamine-formaldehyde polymer, phenolic, polyester, benzoxazine, polydiene, polyisocyanate, polyurea, polyurethane, silicone, liquid crystal elastomer, elastomer, polyimide, triallyl cyanurate polymer, or triallyl isocyanurate polymer, etc., as well as blends, copolymers, etc. of these and/or other polymers.

Non-limiting examples of thermoplastic polymers inculde polyimide (PI), polyamide-imide (PAI), polyetheretherketone (PEEK), polyetherketone (PEK), polyphenylesulfone (PPSU), polyethersulfone (PES), polyetherimide (PEI), polysulfone (PSU), polyphenylene sulfide (PPS), polyvinylidene fluoride (PVDF), polytetrafluoroethylene (PTFE), perfluoroalkoxy alkanes (PFA), polyamide 46 (PA46), polyamide 66 (PA66), polyamide 12 (PA12), polyamide 11 (PA11), polyamide 6 (PA6), polyamide 6.6 (PA6.6), polyamide 6.6/6 (PA6.6/6), amorphous polyamide (PA6-3-T), polyethylene terephthalate (PET), polyphthalamide (PPA), liquid crystal polymer (LCP), polycarbonate (PC), polybutylene terephthalate (PBT), polyoxymethylene (POM), polyphenyl ether (PPE), polymethyl methacrylate (PMMA), polypropylene (PP), polyethylene (PE), high density polyethylene (HDPE), acrylonitrile styrene acrylate (ASA), styrene acrylonitrile (SAN), acrylonitrile butadiene styrene (ABS), polybenzimidazole (PBI), polyvinyl chloride (PVC), poly-para-phenylene-copolymer (PPP), polyacrylonitrile, polyethylenimine, polyetherketonetherketoneketone (PEKEKK), ethylene tetrafluoroethylene (ETFE), polychlorotrifluoroethylene (PCTFE), polymethylpentene, etc. as well as blends, copolymers, etc. of these and/or other polymers. Other examples of thermoplastic and/or thermoset polymers include any of those described herein.

Another aspect is generally directed to systems and methods for making compositions such as those described herein. In one set of embodiments, such compositions can be prepared from a liquid. The liquid may be, for example, a slurry, a solution, an emulsion, or the like. The liquid may contain discontinuous fibers such as discussed herein. The fibers may then be aligned as discussed herein, and the liquid may be then be removed, e.g., to create a fiber-containing substrate. After alignment, the final composition may be formed, for example, by applying heat and/or pressure, e.g., to remove the liquid.

In one set of embodiments, the liquid is able to neutralize the electrostatic interactions between the discontinuous fibers, for example using aqueous liquids. This may be useful, for example, to allow the discontinuous fibers to be dispersed within the liquid at relatively high fiber volumes without agglomeration. In some cases, surfactants and/or alcohols can be introduced into the slurry to reduce electrostatic interactions between the fibers. High shear mixing and flow also may help reduce agglomeration/flocculation in certain cases.

In some embodiments, the liquid phase may include, for example, a thermoplastic or a thermoset, e.g., a thermoplastic solution, thermoplastic melt, thermoset, volatile organic compound, water, or oil. Non-limiting examples of thermosets include phenolics, epoxies, bismaleimides, cyanate esters, polyimides, etc. Additional non-limiting examples of thermosets include thermosetting alkyd, bismaleimide polymer, bismaleimide triazine polymer, cyanate ester polymer, vinyl ester polymer, benzocyclobutene polymer, diallyl phthalate polymer, epoxy, hydroxymethylfuran polymer, melamine-formaldehyde polymer, phenolic, polyester, benzoxazine, polydiene, polyisocyanate, polyurea, polyurethane, silicone, liquid crystal elastomer, elastomer, polyimide, triallyl cyanurate polymer, triallyl isocyanurate polymer, etc. Non-limiting examples of elastomers include silicone rubber and styrene butadiene rubber, etc. Non-limiting examples of thermoplastics include epoxy, polyester, vinyl ester, polycarbonates, polyamides (e.g., nylon, PA-6, PA-12, etc.), polyphenylene sulfide, polyetherimide, polyetheretherketone, polyetherketoneketone, etc. Additional non-limiting examples of thermoplastics include polyimide (PI), polyamide-imide (PAI), polyetheretherketone (PEEK), polyetherketone (PEK), polyphenylesulfone (PPSU), polyethersulfone (PES), polyetherimide (PEI), polysulfone (PSU), polyphenylene sulfide (PPS), polyvinylidene fluoride (PVDF), polytetrafluoroethylene (PTFE), perfluoroalkoxy alkanes (PFA), polyamide 46 (PA46), polyamide 66 (PA66), polyamide 12 (PA12), polyamide 11 (PA11), polyamide 6 (PA6), polyamide 6.6 (PA6.6), polyamide 6.6/6 (PA6.6/6), amorphous polyamide (PA6-3-T), polyethylene terephthalate (PET), polyphthalamide (PPA), liquid crystal polymer (LCP), polycarbonate (PC), polybutylene terephthalate (PBT), polyoxymethylene (POM), polyphenyl ether (PPE), polymethyl methacrylate (PMMA), polypropylene (PP), polyethylene (PE), high density polyethylene (HDPE), acrylonitrile styrene acrylate (ASA), styrene acrylonitrile (SAN), acrylonitrile butadiene styrene (ABS), polybenzimidazole (PBI), polyvinyl chloride (PVC), poly-para-phenylene-copolymer (PPP), polyacrylonitrile, polyethylenimine, polyetherketonetherketoneketone (PEKEKK), ethylene tetrafluoroethylene (ETFE), polychlorotrifluoroethylene (PCTFE), polymethylpente, etc. Non-limiting examples of ceramic monomers include a siloxane, a silazane, or a carbosilane, etc. Combinations of any one or more of the foregoing are also possible in certain embodiments, e.g., as co-polymers, blends, mixtures, or the like. In some cases, for example, one or more of these may be added to assist in homogenously dispersing the discontinuous fibers within the liquid. Examples of volatile organic compounds include, but are not limited to, isopropanol, butanol, ethanol, acetone, toluene, or xylenes.

Any suitable amount of discontinuous fiber may be present in the slurry or other liquid. For instance, at least 10%, at least 15%, at least 20%, at least 25%, at least 30%, at least 35%, at least 40%, at least 45%, at least 50%, at least 55%, at least 60%, at least 65%, at least 70%, at least 75%, or at least 80% of the volume of the slurry may be discontinuous fiber. In some cases, no more than 85%, no more than 80%, no more than 75%, no more than 70%, no more than 65%, no more than 60%, no more than 55%, no more than 50%, no more than 45%, no more than 40%, no more than 35%, no more than 30%, no more than 25%, no more than 20%, no more than 15%, or no more than 10% may be discontinuous fiber. Combinations of any of these are also possible in some cases. For example, a slurry or other liquid may contain between 70% and 80%, between 75% and 85%, between 50% and 90%, etc. discontinuous fiber.

For example, after preparation of the slurry or other liquid, it may be applied to or exposed to a surface, e.g., to form a substrate. Any suitable method may be used to apply the slurry or other liquid to the surface. As non-limiting examples, the liquid may be poured, coated, sprayed, or painted onto the surface, or the surface may be immersed partially or completely within the liquid. The liquid may be used to wet, coat, and/or surround the surface.

A magnetic field may be applied to manipulate the discontinuous fibers, directly or indirectly, as discussed herein, according to one set of embodiments. Any suitable magnetic field may be applied. In some cases, the magnetic field is a constant magnetic field. In other cases, the magnetic field may be time-varying; for example, the magnetic field may oscillate or periodically change in amplitude and/or direction, e.g., to facilitate manipulation of the discontinuous agents. The oscillation may be sinusoidal or another repeating waveform (e.g., square wave or sawtooth). The frequency may be, for example, at least 0.1 Hz, at least 0.3 Hz, at least 0.5 Hz, at least 1 Hz, at least 3 Hz, at least 5 Hz, at least 10 Hz, at least 30 Hz, at least 50 Hz, at least 100 Hz, at least 300 Hz, at least 500 Hz, etc., and/or no more than 1000 Hz, no more than 500 Hz, no more than 300 Hz, no more than 100 Hz, no more than 50 Hz, no more than 30 Hz, no more than 10 Hz, no more than 5 Hz, no more than 3 Hz, etc. For example, the frequency may be between 1 Hz to 500 Hz, between 10 Hz and 30 Hz, between 50 Hz and Hz, or the like. In addition, the frequency may be held substantially constant, or the frequency may vary in some cases.

The magnetic field, whether constant or oscillating, may have any suitable amplitude. For example, the amplitude may be at least 0.001 T, at least 0.003 T, at least 0.005 T, at least 0.01 T, at least 0.03 T, at least 0.05 T, at least 0.1 T, at least 0.3 T, at least 0.5 T, at least 1 T, at least 3 T, at least 5 T, at least 10 T, etc. The amplitude in some cases may be no more than 20 T, no more than 10 T, no more than 5 T, no more than 3 T, no more than 1 T, no more than 0.5 T, no more than 0.3 T, no more than 0.1 T, no more than 0.05 T, no more than 0.03 T, no more than 0.01 T, no more than 0.005 T, no more than 0.003 T, etc. The amplitude may also fall within any combination of these values. For instance, the amplitude may be between 0.01 T to 10 T, between 1 T and 3 T, between 0.5 T and 1 T, or the like. The amplitude may be substantially constant, or may vary in certain embodiments, e.g., within any range of these values.

In some embodiments, the magnetic field direction (i.e., direction of maximum amplitude) may vary by +/−90°, +/−85°, +/−80°, +/−75°, +/−70°, +/−65°, +/−60°, +/−55°, +/−50°, +/−45°, +/−40°, +/−35°, +/−30°, +/−25°, +/−20°, +/−15°, +/−10°, +/−5° about a mean direction.

A variety of different devices for producing suitable magnetic fields may be obtained commercially, and include permanent magnets or electromagnets. In some cases, an oscillating magnetic may be created by attaching a magnet to a rotating disc and rotating the disc at an appropriate speed or frequency. Non-limiting examples of permanent magnets include iron magnets, alnico magnets, rare earth magnets, or the like.

In one set of embodiments, shear flow may be used to align or manipulate the discontinuous fibers. For example, a shearing fluid may be applied to the substrate to cause at least some of the plurality of discontinuous agents to align, e.g., in the direction of shear flow. Examples of shearing fluids that may be used include water, or another liquid, such as oil, an alcohol such as ethanol, an organic solvent (e.g., such as isopropanol, butanol, ethanol, acetone, toluene, or xylenes), or the like. In certain embodiments, the shearing fluid may have a viscosity of at least 1 cP. In addition, in some cases, the shearing fluid may be a gas, such as air. The linear flow rate of the shearing fluid, may be, for example, at least 10 mm/min, at least 20 mm/min, at least 30 mm/min, at least 50 mm/min, at least 100 mm/min, at least 200 mm/min, at least 300 mm/min, etc.

For example, in one set of embodiments, the fibers can be added to a liquid, including an alcohol, solvent, or resin, to form a slurry. The slurry can be flowed to align the fibers in some cases, e.g., wherein the slurry is used as a shearing fluid. In other cases, however, the slurry may first be applied to a substrate, then a shearing fluid used to align the fibers.

In addition, in some embodiments, mechanical vibration may be used to manipulate the discontinuous fibers, e.g., in addition to and/or instead of magnetic manipulation and/or shear flow. For example, mechanical vibration can be used to move discontinuous fibers into or on the substrate, e.g., into pores or holes within the substrate, and/or at least to substantially align the discontinuous agents within the substrate, e.g., as discussed herein. In one set of embodiments, mechanical vibration may be applied to cause motion of the discontinuous fibers of at least 1 micrometer, at least 2 micrometers, at least 3 micrometers, at least 5 micrometers, at least 10 micrometers, at least 20 micrometers, at least 30 micrometers, at least 50 micrometers, at least 100 micrometers, at least 200 micrometers, at least 300 micrometers, at least 500 micrometers, at least 1,000 micrometers, at least 2,000 micrometers, at least 3,000 micrometers, at least 5,000 micrometers, or at least 10,000 micrometers.

In addition, in some cases, the mechanical vibrations may be time-varying; for example, the mechanical vibrations may periodically change in amplitude and/or direction, e.g., to facilitate manipulation of the discontinuous fibers. The oscillation may be sinusoidal or another repeating waveform (e.g., square wave or sawtooth). The frequency may be, for example, at least 0.1 Hz, at least 0.3 Hz, at least 0.5 Hz, at least 1 Hz, at least 3 Hz, at least 5 Hz, at least 10 Hz, at least 30 Hz, at least 50 Hz, at least 100 Hz, at least 300 Hz, at least 500 Hz, etc., and/or no more than 1000 Hz, no more than 500 Hz, no more than 300 Hz, no more than 100 Hz, no more than 50 Hz, no more than 30 Hz, no more than 10 Hz, no more than 5 Hz, no more than 3 Hz, etc. For example, the frequency may be between 1 Hz to 500 Hz, between 10 Hz and 30 Hz, between 50 Hz and Hz, or the like. In addition, the frequency may be held substantially constant, or the frequency may vary in some cases. If applied in conjunction with an oscillating magnetic field, their frequencies may independently be the same or different.

During and/or after alignment, the discontinuous fibers may be set or fixed in some embodiments, e.g., to prevent or limit subsequent movement of the discontinuous fibers, in one set of embodiments. Non-limiting examples of techniques include, but are not limited to solidifying, hardening, gelling, melting, heating, evaporating, freezing, lyophilizing, or pressing the liquid or the slurry.

In some cases, the liquid may comprise a relatively volatile solvent, which can be removed by heating and/or evaporation (e.g., by waiting a suitable amount of time, or allowing the solvent to evaporate, e.g., in a fume hood or other ventilated area). Non-limiting examples of volatile solvents include isopropanol, butanol, ethanol, acetone, toluene, or xylenes. Other examples of methods of removing solvents include applying vacuum, lyophilization, mechanical shaking, or the like.

In one set of embodiments, heating may be applied to the discontinuous fibers, for example, to dry the liquid or remove a portion of the solvent. For example, the discontinuous fibers may be heated to a temperature of at least about 30° C., at least about 35° C., at least about 40° C., at least about 45° C., at least about 50° C., at least about 55° C., at least about 60° C., at least about 65° C., at least about 70° C., at least about 75° C., at least about 80° C., at least about 90° C., at least about 100° C., at least about 125° C., at least about 150° C., at least about 175° C., at least about 200° C., at least about 250° C., at least about 300° C., at least about 350° C., at least about 400° C., at least about 450° C., at least about 500° C., etc. Any suitable method of applying heat may be used, for example, a thermoelectric transducer, an Ohmic heater, a Peltier device, a combustion heater, or the like. In some cases, the viscosity of the liquid may decrease as a result of heating. The heating may be applied, for example, prior, concurrent or subsequent to the application of magnetic field and/or mechanical vibration.

Thus, in one set of embodiments, a first coating may be applied onto a plurality of discontinuous fibers, which may be substantially aligned as discussed herein. The first coating may be applied onto at least one surface, or an interior plane, etc., of the plurality of discontinuous fibers as a coating and/or film. The coating may include, for example, a phase change material, polymer, or the like, e.g., as discussed herein. In some cases, the coating may comprise a filler, such as a ceramic, a metal, etc., e.g., as described herein. The coating may be applied to the plurality of discontinuous fibers as discussed herein, for example, using gravity, capillary action, heat, pressure, etc.

In addition, in some embodiments, a second coating may be applied to at least one surface of the composition, e.g., a coating and/or film. The second coating material may comprise the same material as the primary coating, or a different material. The coating may be applied as discussed herein, for example, using gravity, capillary action, heat, pressure, etc., and the same technique, or a different technique, may be used.

In addition, in some aspects, a material such as a phase change material, or other materials such as those discussed herein, may be added to the discontinuous fibers. The material may be applied at any suitable point, e.g., before, during, and/or after formation or alignment of the discontinuous fibers, e.g., to form a substrate. The material may be applied as a liquid in some cases, and may be caused to harden after application to the discontinuous fibers. In some cases, the material is permeated into at least a portion of the discontinuous fibers. Non-limiting examples of permeation techniques include using gravitational and capillary forces, by applying pressure to the material to force it into the discontinuous fibers, or the like. Heat may be applied in some embodiments. Other examples include, but are not limited to, hot-pressing, calendaring, or vacuum infusion. However, in some cases, the material is used to coat all, or only a portion of, the discontinuous fibers, e.g., without necessarily requiring permeation or embedding of the discontinuous fibers completely within the material (although these may also be achieved in yet other embodiments). For instance, in certain embodiments, at least 10%, at least 20%, at least 30%, at least 40%, at least 50%, at least 60%, at least 70%, at least 80%, or at least 90% of the lengths of the discontinuous fibers may not be in contact with the phase change material

In some cases, the pressure may be used to also remove some of the liquid from the discontinuous fibers. Examples include, but are not limited to, hot-pressing, calendaring, vacuum infusion, or the like. The pressure that is applied, may be, for example, at least 15 psi (gauge), at least 30 psi, at least 45 psi, etc. (1 psi=6895 Pa.)

In some embodiments, heat may be applied to facilitate application of the material. This may be useful, for example, to partially or completely liquefy or soften the material, or facilitate its flow or permeation, e.g., to surround the discontinuous fibers. For example, in one set of embodiments, the material may be heated to temperature of at least 30° C., at least 40° C., at least 50° C., at least 60° C., at least 70° C., at least 80° C., at least 90° C., etc.

In one aspect, a composition such as discussed herein may be used to conduct heat between a first location (e.g., a heat source) and a second location (e.g., a heat sink or a cooling apparatus). The heat source may be any suitable source of heat. For example, in one embodiment, the heat source may be a semiconductor device, e.g., for use in a computer or other electronic device. The semiconductor device may be, for example, a CPU, GPU, RAM module, power transistor, laser, light-emitting diode, photovoltaic cell, or the like. Other heat sources may be used in some embodiments as well. For example, in one embodiment, the heat source may involve a chemical reaction or an electrical system (e.g., resistive heating).

The heat sink or cooling apparatus may be any apparatus able to dissipate heat. As non-limiting examples, the heat sink may include a fluid medium, such as air or a liquid. For example, the heat sink may include a fan to blow air to cool the apparatus, or a pump that applies a liquid coolant. In some cases, the heat sink may include a plurality of fins that the fluid is able to pass through, thereby allowing heat transfer to the fluid to occur in the heat sink. The fins may have any shape, e.g., including pin, straight, flared, slanted, or the like. The fins may have any suitable cross section, including cylindrical, elliptical, square, etc.

The heat sink may include materials such as copper, aluminum, zinc, magnesium, nickel, or other metals with relatively high heat conductivities, in certain embodiments. In some cases, alloys or mixtures of these and/or other metals are also possible. In addition, the metal may be solid, or porous in some embodiments.

In addition, in some embodiments, the heat sink may include ceramics. For example, the ceramic may include materials such as boron nitride, titanium diboride, aluminum nitride, silicon nitride, silicon carbide, graphite, aluminum oxide, magnesium oxide, zinc oxide, beryllium oxide, antimony oxide, silicon oxide. Combinations of these and/or other materials are also possible. In addition, the ceramic may be solid, or porous in some embodiments.

As discussed, the composition may be used to help thermally communicate a first location to a second location. The composition may be positioned in direct physical contact with one or both of the heat source and the cooling apparatus, and/or there may be other materials that help facilitate the transport of heat from the heat source to the cooling apparatus. Non-limiting examples include thermal tape (e.g., polyimide, graphite, aluminum, etc.), epoxy, grease, solder, silicone coated fabrics, or other thermal interface materials.

The following documents are incorporated herein by reference in their entireties: Int. Pat. Apl. Pub. No. WO 2018/175134, entitled “Fiber-Reinforced Composites, Methods Therefore And Articles Comprising The Same”; Int. Pat. Apl. Pub. No. WO 2020/123334, entitled “Systems and Methods for Carbon Fiber Alignment and Fiber-Reinforced Composites”; Int. Pat. Apl. Pub. No. WO 2021/007381, entitled “Systems and Methods for Forming Short-Fiber Films, Composites Comprising Thermosets, and Other Composites”; and Int. Pat. Apl. Pub. No. WO 2021/007389, entitled “Compositions and Methods for Carbon Fiber-Metal Composites.” In addition, U.S. Provisional Patent Application Ser. No. 63/314,808, filed Feb. 28, 2022, entitled “Thermally Conductive Aligned Materials and Methods of Making and Use Thereof,” is also incorporated herein by reference in its entirety.

The following examples are intended to illustrate certain embodiments of the present disclosure, but do not exemplify the full scope of the disclosure.

### Example 1

A sample composition in accordance with one embodiment is shown in FIG. 1. The sample in this example was prepared by coating a Z-axis carbon fiber film (see, e.g., Int. Pat. Apl. No. WO 2021/007381, incorporated herein by reference) with a water-based slurry of boron nitride nanoparticles. The water is evaporated, leaving behind a dense coating of boron nitride on one surface of the Z-axis fiber film. The Z-axis carbon fiber film in this example was made using a pitch-based carbon fiber that had a thermal conductivity of 900 W/m K in the long-axis direction. The Z-axis fiber film has an areal weight of 120 grams per square-meter.

### Example 2

This example illustrates a composition with vertically aligned carbon fibers at 50% fiber volume fraction embedded in paraffin wax. The composition is coated with a phase change compound comprised of paraffin wax and thermally conductive fillers. The coating is 76 microns in thickness and located on the top surface of the composition. When tested per ASTM D5470, this composition has a thermal impedance (RA) of 0.033 K-in²/W (0.213 K cm²/W) at 50 psi (345 kPa). An SEM of this composition is shown in FIG. 2.

### Example 3

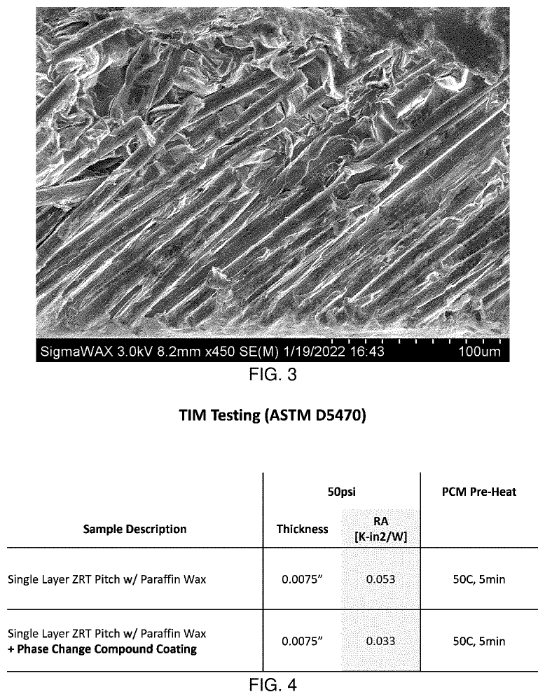

This example illustrates a composition with vertically aligned carbon fibers at 50% fiber packing efficiency coated with a paraffin wax film. When the composition is heated to 60° C., the viscosity of the paraffin wax is sufficiently low enough to infuse into the vertically aligned carbon fiber. When tested per ASTM D5470, this composition has a thermal impedance (RA) of 0.053 K in²/W (0.342 K cm²/W) at 50 psi (345 kPa). FIG. 3 is an SEM image of this composition, while FIG. 4 illustrates the thickness and thermal impedance of this composition.

### Example 4

In this prophetic example, a central processing unit (CPU) of a notebook personal computer is cooled using one embodiment. The cooling apparatus in this example is a copper vapor chamber. An aligned carbon fiber composition with 50% fiber volume fraction with paraffin wax is prepared, where the carbon fibers are pitch-based and have a thermal conductivity along the long-axis of 900 W/m K. The composition has a bulk conductivity of 40 W/m-K. The composition is used to attach the copper vapor chamber to the CPU unit, thereby conducting heat from the CPU to the copper vapor.

### Example 5

In this prophetic example, a graphic processing unit (GPU) of an autonomous driving vehicle is cooled using one embodiment. The cooling apparatus in this example is an air-cooled aluminum fin heat exchanger. An aligned carbon fiber composition with 50% fiber volume fraction with paraffin wax is prepared, where the carbon fibers are pitch-based and have a thermal conductivity along the long-axis of 900 W/m K. The composition has a bulk conductivity of 60 W/m K in the through-thickness direction and 2 W/m K in the in-plane direction. The composition is used to attach the aluminum fin heat exchanger to the GPU unit, thereby conducting heat from the GPU to the heat exchanger.

### Example 6

In this prophetic example, a lithium-ion battery within a battery pack is cooled using one embodiment. The cooling apparatus in this example is a cold plate. An aligned carbon fiber composition with 50% fiber volume fraction with paraffin wax is prepared, where the carbon fibers are pitch-based and have a thermal conductivity along the long-axis of 900 W/m K. The composition has a bulk conductivity of 30 W/m K in the through-thickness direction and 1 W/m K in the in-plane direction. The composition is used to attach the cold plate to the battery pack, thereby conducting heat from the battery to the cold plate. The paraffin wax of the composition undergoes an endothermic phase change at 50° C., consuming a component of the heat flux generated by the lithium-ion battery.

While several embodiments of the present disclosure have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present disclosure. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present disclosure is/are used. Those skilled in the art will recognize, or be able to ascertain using no more than routine experimentation, many equivalents to the specific embodiments of the disclosure described herein. It is, therefore, to be understood that the foregoing embodiments are presented by way of example only and that, within the scope of the appended claims and equivalents thereto, the disclosure may be practiced otherwise than as specifically described and claimed. The present disclosure is directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present disclosure.

In cases where the present specification and a document incorporated by reference include conflicting and/or inconsistent disclosure, the present specification shall control. If two or more documents incorporated by reference include conflicting and/or inconsistent disclosure with respect to each other, then the document having the later effective date shall control.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.”

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

When the word “about” is used herein in reference to a number, it should be understood that still another embodiment of the disclosure includes that number not modified by the presence of the word “about.”

It should also be understood that, unless clearly indicated to the contrary, in any methods claimed herein that include more than one step or act, the order of the steps or acts of the method is not necessarily limited to the order in which the steps or acts of the method are recited. In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

What is claimed is:

1-122. (canceled)

123. A composition, comprising:
a substrate comprising no more than 30 vol % of a metal, wherein the substrate has a density of less than 2.7 g/cm³ and a heat conductivity of at least 5 W/m K; and
a phase change material in contact with at least some discontinuous fibers, wherein the phase change material exhibits a phase change between 0° C. and 300° C.

124. The composition of claim 123, wherein the substrate is free of metal.

125. The composition of claim 123, wherein at least 50 vol % of the substrate comprises carbon fibers.

126. The composition of claim 125, wherein at least 30 vol % of the fibers within the substrate are substantially aligned.

127. The composition of claim 123, wherein the substrate has a heat conductivity of at least 5 W/m K in a through-thickness direction.

128. The composition of claim 123, wherein the substrate has a heat conductivity of at least 20 W/m K in a through-thickness direction.

129. The composition of claim 123, wherein the substrate comprises a metal.

130. The composition of claim 123, wherein the substrate comprises a ceramic.

131. The composition of claim 123, wherein the substrate comprises a polymer.

132. The composition of claim 131, wherein the polymer comprises a thermoplastic polymer.

133. The composition of claim 131, wherein the polymer comprises a thermoset polymer.

134-136. (canceled)

137. A device, comprising:
a heat source;
a cooling apparatus; and
a composition in physical contact with the heat source and the cooling apparatus,
wherein the composition comprises (a) a substrate comprising no more than 30 vol % of a metal, wherein the substrate has a density of less than 2.7 g/cm³ and a heat conductivity of at least 5 W/m K, and (b) a phase change material in contact with at least some discontinuous fibers, wherein the phase change material exhibits a phase change between 0° C. and 300° C.

138. The device of claim 137, wherein the substrate is free of metal.

139. The device of claim 137, wherein at least 50 vol % of the substrate comprises carbon fibers.

140. The device of claim 139, wherein at least 30 vol % of the fibers within the substrate are substantially aligned.

141. The device of claim 137, wherein the substrate has a heat conductivity of at least 5 W/m K in a through-thickness direction.

142-150. (canceled)

151. A composition, comprising:
a substrate having a density of less than 2.7 g/cm³ and exhibiting an anisotropic heat conductivity of at least 5 W/m K in a through-thickness direction.

152. The composition of claim 151, wherein at least 50 vol % of the substrate comprises carbon fibers.

153. The composition of claim 152, wherein at least 30 vol % of the fibers within the substrate are substantially aligned.

154-155. (canceled)

156. The composition of claim 152, wherein at least 50% of the fibers have an alignment that is within 20° of the average alignment of the fibers.

157-165. (canceled)
